(19) United States
(12) Patent Application Publication
(10) Pub. No.: US 2026/0262485 A1
(43) Pub. Date: Sep. 3, 2026

(54) VIA STRUCTURES FOR HYBRID BONDING ARCHITECTURES

(71) Applicant: Intel Corporation, Santa Clara, CA (US)

(72) Inventors: Mohammad Enamul Kabir, Portland, OR (US); Adel A. Elsherbini, Chandler, AZ (US); Shawna M. Liff, Scottsdale, AZ (US); Golsa Naderi, Portland, OR (US); Saurabh Chauhan, Beaverton, OR (US)

(73) Assignee: Intel Corporation, Santa Clara, CA (US)

(21) Appl. No.: 19/066,922

(22) Filed: Feb. 28, 2025

(51) Int. Cl. H01L 23/48; H01L 23/00; H01L 25/065

(52) U.S. Cl. CPC H10W 20/20; H10W 90/00; H10W 90/297; H10W 90/724; H10W 90/792

(57) ABSTRACT

Via structures for hybrid bonding architectures, and methods for making same. The structures include a die with a plurality of conductive contacts arranged at a pitch of less than about 4 microns in a hybrid bonding interface. The first layer of metal is below the plurality of conductive contacts, and a second layer of metal is below the first layer of metal and separated therefrom by an insulating layer. A via structure in the die comprises copper or tungsten and is electrically coupled at a first end to a first conductive contact of the plurality of conductive contacts and electrically coupled at a second end to the second layer of metal. A second conductive contact located sequentially next to the first conductive contact is electrically coupled to the first layer of metal.

### BACKGROUND

Hybrid bonding architectures are desirable for a variety of reasons, one of them being the fine pitch that they support. However, as technology progresses, the pitch between these hybrid bond pads is being decreased. As the hybrid bonding pitch is decreased, achieving the needed maximum currents presents a technical challenge.

### BRIEF DESCRIPTION OF THE DRAWINGS

FIG. 1A is a simplified cross-sectional image of a microelectronic assembly, depicting the via structures and uniform pitch between power/ground hybrid bond contacts and signal hybrid bond contacts.

FIG. 1B is a simplified top-down or plan view of the microelectronic assembly of FIG. 1A, in accordance with any of the embodiments disclosed herein.

FIG. 2 is a simplified cross-sectional illustration of an exemplary via structure in a microelectronic assembly, in accordance with any of the embodiments disclosed herein.

FIG. 3 is a simplified example of a multi-die assembly based on any of the embodiments disclosed herein.

FIG. 4 is an example method for making embodiments described herein.

FIG. 5 is a top view of a wafer and dies that may be included in a microelectronic assembly, in accordance with any of the embodiments disclosed herein.

FIG. 6 is a cross-sectional view of an integrated circuit device that may be included in any of the microelectronic assemblies disclosed herein.

FIGS. 7A-7D are perspective views of example planar, FinFET, gate-all-around, and stacked gate-all-around transistors.

FIG. 8 is a cross-sectional view of an integrated circuit device assembly that may include a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

Hybrid bonding architecture offers many benefits, one of them being the fine pitch that they support. Available hybrid bonding architectures often require a dedicated via layer (sometimes called the GVH layer, for “great via hybrid bond”) under the hybrid bonding pads (MPH layer). The vias created in the via layer have smaller critical dimensions (CDs) than the hybrid bonding pads they electrically couple to, based in part on their sidewall taper.

As technology progresses, the pitch between these hybrid bond pads is being decreased, creating narrower vias, and reducing the maximum current (Imax) that can be supported. This presents a technical challenge for some available solutions, at least in part because of the processing related to a via layer. The via trenches are etched, thus, they are prone to taper. The via trenches are etched in the silicon nitride during processing. Silicon nitride is prone to the formation of highly tapered vias. For example, an 1100 nm (nanometer) drawn critical dimension can result in approximately an 800 nm final critical dimension. This tapering is undesirable as it poses a significant challenge to chemical etching. Moreover, the reduced critical dimensions can result in highly resistive vias and increased power dissipation.

Some solutions depend on defining an Imax limit on the via structures and requiring the addition of more bonding pads to meet power delivery requirements. A drawback of this approach is that it affects the area required at the interface, which can manifest as a larger die or as a die with less area available for signal connections. These results are undesirable reductions in performance.

Embodiments provide a technical solution to this technical problem. The proposed architecture and methods enable continuous scaling of the hybrid bond pitch without power delivery limitations. The via structures (“supervias”) described herein enable the use of a thicker top layer of metal (power delivery layer) in microelectronic assemblies. Additionally, the supervias enable a smaller pitch that can support the higher power and higher current (Imax) that applications require.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

As used herein, “connected” indicates that elements are in direct physical or electrical contact with each other and “coupled” indicates elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, layers, faces, or features that are referred to as being substantially parallel can refer to layers, faces, or features that are within 2-5 degrees of being parallel with each other, and layers, faces, or features that are referred to as being substantially perpendicular to each other can refer to features that are within +/−15 degrees of being perpendicular to each other.

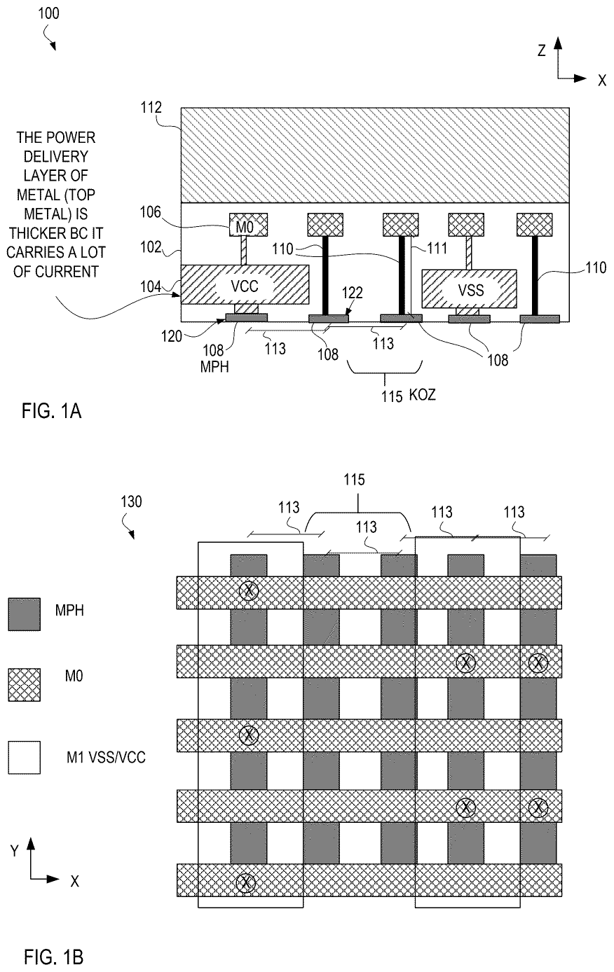

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 1A, the via structures 110 are located on respective conductive contacts 108 (MPH).

Certain terminology may also be used herein for the purpose of reference only and thus are not intended to be limiting. For example, terms such as “upper,” “lower,” “above,” “below,” “bottom,” and “top” refer to directions on the page in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the phrase “electrically coupled” refers to the presence of one or more electrically conductive paths between components that are recited as being electrically coupled.

Reference is now made to the drawings, which are not necessarily drawn to scale, wherein similar or same numbers may be used to designate same or similar parts in different figures. The drawings illustrate generally, by way of example, but not by way of limitation, various embodiments discussed in the present document. It is to be understood that drawings illustrate idealized versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

Turning now to FIG. 1A and FIG. 1B, embodiments introduce a sub-four-micron (less than 4 micron+10%) hybrid bond pad pitch for microelectronic assemblies that does not limit Imax. In various embodiments, this architecture implements a new via structure (“supervias”) for fine pitch (i.e., hybrid bond pitch) die-to-die signaling and via-to-via hybrid bonds that are larger than the bonding pads available methods use for power delivery.

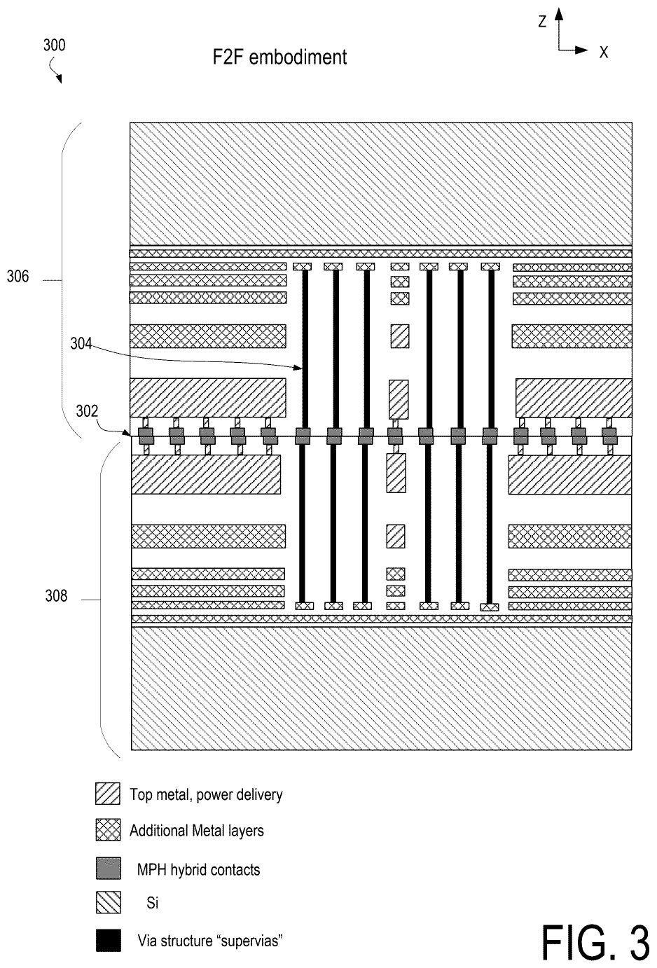

Hybrid bonding (also, HB, and HBI) is referenced herein. Hybrid bonding, also called direct bond interconnect (DBI) is a packaging technology that involves bringing together the surfaces of two semiconductor devices under applied pressure and/or at elevated temperature, generally as a die stacking solution, resulting in dielectric-to-dielectric bonding and metal-to-metal bonding (without solder and without underfill). HBI advantageously enables “small” pitches (defined herein as a pitch less than 10 microns+/−20%, and in some cases, the pitch is less than 1 micron+/−20%) between neighboring conductive contacts. For reference, FIG. 3 illustrates two dies that are hybrid bonded together.

FIG. 1A is a simplified cross-sectional image depicting the via structures 110 (“supervias”) in an embodiment 100. A semiconductor substrate 102 comprises an insulating material (e.g., silicon oxide (SiOx)) with metal traces, vias, and interconnects therein. The semiconductor substrate 102 has a first surface (the upper surface in the figure) and a second surface (the lower surface in the image). The first surface may comprise, or be overlaid with, a layer 112 of silicon.

The second surface includes the insulating material with a plurality of conductive contacts, 108 arranged therein. The conductive contacts 108 are metal pad hybrid (MPH) bond pads, and they are arranged at a pitch 113 of less than about 4 microns. As used herein, “about” means plus/minus 10%.

Below the conductive contacts 108 (which appears “above” in the figure, is a first layer 104 of metal (e.g., metal 1, M1). In various embodiments, the first layer of metal may be referred to as the top metal, the power delivery layer of metal, Vss/Vcc layer, etc., because it is thicker (as illustrated in FIG. 1B), is used to create electrical pathways for power and ground and carries substantially more current than other metal layers in the semiconductor substrate 102. The first conductive contact 120 of the plurality of conductive contacts is electrically coupled to the first layer 104 of metal.

Below the first layer of metal, and separated therefrom by an insulating layer (e.g., part of the semiconductor substrate 102), is a second layer of metal (e.g., metal 0, M0 106). The second layer of metal, M0, may be to provide electrical pathways for signals, such as command and data lines. A second conductive contact 122, next to the first conductive contact, is electrically coupled to the second layer of metal. As used herein, “next to” means that it is sequentially the next conductive contact in the arrangement at the pitch 113. Accordingly, the first conductive contact 120 and the second conductive contact 122 are less than about 4 microns apart. Advantageously, embodiments provide a uniform pitch between power/ground hybrid bond contacts and signal hybrid bond contacts.

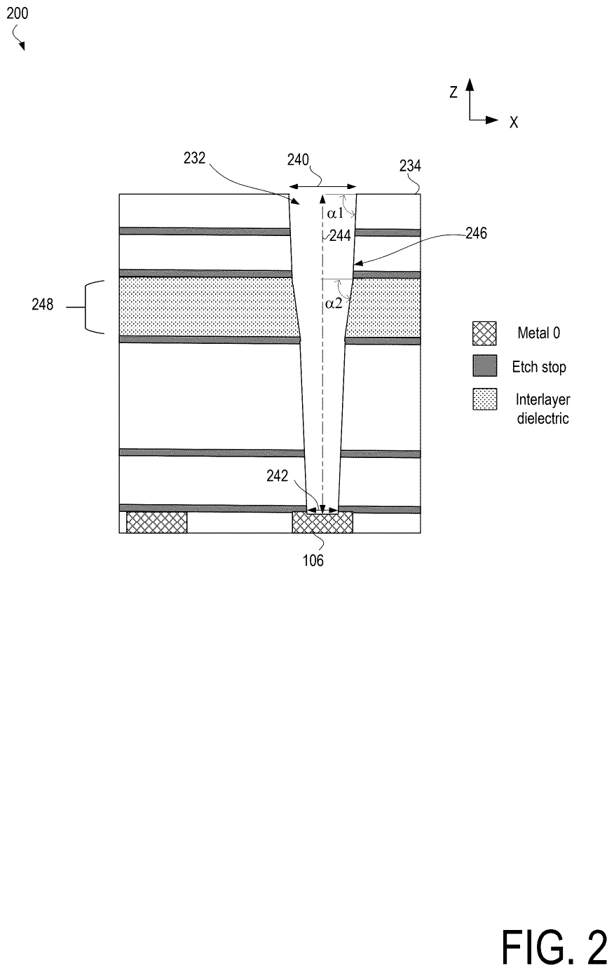

The uniform pitch 113 is enabled with embodiments of the “supervia,” illustrated as via structures 110. Notably, the via structures 110 orthogonally extend through a keep out zone (KOZ 115) in the plane of the Vss/Vcc metal, first layer 104 of metal, and “land on” or connect with a different layer of metal, deeper in the semiconductor backend stack-up of substrate 102. In FIG. 1A, the via structures 110 are electrically coupled to traces of M0 106, the second layer of metal. However, in other embodiments, the via structures 110 may extend to even deeper layers of metal (see, e.g., FIG. 3). The via structures 110 can be described by an aspect ratio of a surface diameter and height/depth 111. Looking forward to FIG. 2, the aspect ratio is the first diameter 240 value divided by the height or [trench] depth 244. In various embodiments, the aspect ratio is about 1/10.

FIG. 1B is a simplified top-down or plan view that corresponds to FIG. 1A. Embodiment 130 depicts the conductive contacts 108 or MPH metal in a shade of grey. The layer of metal used for signals, second layer of metal (e.g., metal 0, M0 106) is depicted with hatched fill, and the first layer 104 of metal (e.g., metal 1, M1) is depicted with no fill so that the lower-level metal can be visualized through it. FIG. 1B provides additional understanding of the uniformity of the pitch 113 between both Vcc/Vss conductive contacts and signal conductive contacts and also illustrates the KOZ 115.

In various embodiments, the first layer 104 of metal has a thickness depicted left to right on the page of FIG. 1B. The first layer 104 of metal may have a thickness that is larger than thicknesses of mid-level layers of metal, and mid-level layers of metal may have thicknesses that are larger than the lowest layer of metal. In a non-limiting example, the first layer of metal has a thickness of about 4.5 microns. In various embodiments, the lowest layer of metal in a silicon metal stack has a thickness in the nanometer range. Moreover, the larger the thickness of the metal, the larger the pitch required for via structures/interconnects.

Moving to FIG. 2, and with continued reference to FIGS. 1A and 1B, embodiment 200 is a simplified enlargement of a “supervia” or via structure 232 within a semiconductor backend stack-up, for discussion. While FIG. 2 is not to-scale, it can be relied upon for depicting spatial relationships and orientations, as described herein. FIG. 2 generally corresponds to a 180 degree flip of the image of FIG. 1A. The semiconductor backend stack-up in FIG. 2 comprises a plurality of etch-stop layers and associated “interlayer” dielectric layers. Further, etch-stop layers generally have an associated via layer and the “interlayer” dielectric layers generally have an associated metal layer (the metal layers have been omitted to simplify the image). The interlayer dielectric layer 248 is a non-conducting material, and may comprise the insulating material (e.g., silicon oxide (SiOx)) of the semiconductor substrate 102. In a non-limiting embodiment, the etch-stop layer comprises silicon, carbon, and nitrogen, e.g., SiCN. In another non-limiting embodiment, the interlayer dielectric layer comprises silicon and nitrogen, e.g., SiN.

Embodiments of the provided via structure 232 extend orthogonally from the surface 234 into the semiconductor backend stack-up of the silicon substrate 102, through one or more etch-stop and interlayer dielectric layers, and lands on/or electrically connects with an M0 106 conductive contact. The via structure 232 has a first end and a second end, and a continuous sidewall 246 from the first end to the second end. The first end is the end from which the via structure 232 was created/etched; it has a larger critical dimension (CD) or diameter 240 than the diameter 242 at the bottom of the via structure 232, or second end. The via structure 232 may comprise copper or tungsten within its sidewall, sufficient to create an electrical path from the first end to the second end. In some non-limiting embodiments, the via structure comprises 232 tungsten doped carbon (WDC) or amorphous carbon (AC) (also referred to as reactive carbon). In practice, the second end is electrically coupled to the second conductive contact 122 and the first end is electrically coupled to a non-power-delivery layer of metal, e.g., to at least the second layer 106 of metal.

As mentioned before, the via structure 232 has an aspect ratio described by diameter 240/depth 244. The via structure 232 may also be described as having an overall taper from the first end to inward the second end; in various embodiments, the second diameter 242 is about 70% of the first diameter 240. Furthermore, the via structure 232 may be described as comprising multiple segments, wherein individual segments may have different localized slopes that collectively add up to the overall taper. For example, measured as shown from the surface 234, angle alpha 1 may be a first angle, creating a first slope for a first segment of the via structure. A second segment of the via structure may comprise a second slope represented by a second angle (alpha 2, as indicated), and so on to the second end. In various embodiments, the second angle is more than 5 degrees smaller than the first angle. The second segment may be associated with an interlayer dielectric layer (such as SiN) and may have a steeper taper for reasons described above.

In a non-limiting example, some segments of the multiple segments correspond to a layer of a dielectric material between two layers of an etch stop (such as, but not limited to a material comprising silicon, carbon, and nitrogen (e.g., SiCN)).

Advantageously, the number of metal layers of the semiconductor backend stack-up that the via structure 232 may extend through is limited only by its aspect ratio, and the aspect ratio can be controlled by the chemical etch process. During the manufacturing process, the recipe for the chemical etch process can be changed on a per-layer basis, to control the sidewall taper (i.e., segment by segment) as one travels from the upper surface 234 to the bottom/second end of the via structure 232. Embodiments provide a larger critical dimension (CD) via structure that is capable of carrying higher current than other approaches that scale the hybrid bond contacts.

Embodiments can be recognized using SEM images focused on a cross-sectional area where the herein described via structures (“supervias”) and characteristic sidewalls can be found. The via structures will have therein either pure metals (e.g., copper or tungsten), or doped metal (e.g., tungsten doped copper), and the MPH pitch will be the sub-4-micron pitch, in particular, the fine pitch between signal MPH pads and power deliver MPH pads can be observed.

Embodiments make use of the very fine pitch capability of hybrid bonding to connect die/chiplets or even wafers. Embodiment 300 in FIG. 3 illustrates a multi-die package in which the first die 306 is hybrid-bonded in a face-to-face (F2F) configuration to a second die 308 at the hybrid bonding interface 302. With reference to FIG. 1A, the top metal layer or top power delivery layer is depicted with the right-leaning diagonals, and subsequent lower-level metal layers are depicted with hatched shading. The dies are understood to include respective integrated circuits, and the supervias or via structures 304 are to provide electrical coupling from hybrid bonds at the respective faces to signal nodes within the integrated circuits. The hybrid bond conductive contacts are at the pitch described above.

In a generalized description of the hybrid bonding process and result, a first semiconductor die is fabricated with layers of insulating material or dielectric material, interspersed with conductive interconnects (vias and traces), building up to a hybrid bond (HB) surface. At least one hybrid bond conductive contact (sometime called a HB pad) is exposed at the HB surface. Likewise, a second die is similarly constructed and has a second HB surface with at least one corresponding HB conductive contact. The HB conductive contacts (shortened herein to conductive contacts) are conductive, generally comprising a metal, such as copper (Cu). In some embodiments, the HB conductive contacts may include one or more of gold, tungsten, aluminum, titanium, tantalum, molybdenum, magnesium, and cobalt (W, Mo, Ti, Au, Mg, Ta, Co, Al) or tertiary systems or designer grain systems.

The conductive contacts are surrounded by (in a plan view at their respective HB surface) the insulating or dielectric material. More specifically, every individual metal/Cu contact has dielectric material in physical contact with it and surrounding it. When the first die is described as hybrid bonded to the second die, what is seen in a SEM image is an HB interface (e.g., FIG. 3, HB interface 302), characterized by insulating or dielectric material of the first die bonded directly to the insulating or dielectric material of the second die (e.g., SiOx to SiOx, SiOxNy to SiOxNy, intralevel dielectric insulator (ILD), ultra-low dielectric constant (ultra-low k) dielectric, or the like) and conductive contacts from the first die are direct metal bonded to respective conductive contacts of the second die, and there is no solder material, and no underfill, at the HB interface. In most applications, at least one HB conductive contact is coupled to the integrated circuitry of an active region in an integrated circuit die, e.g., via a through silicon via (TSV). In various aspects of the disclosure, the HB conductive contacts are to provide an electrical path from respective nodes in the active regions of an integrated circuit through the bonding layers and are exposed at the HB surface(s).

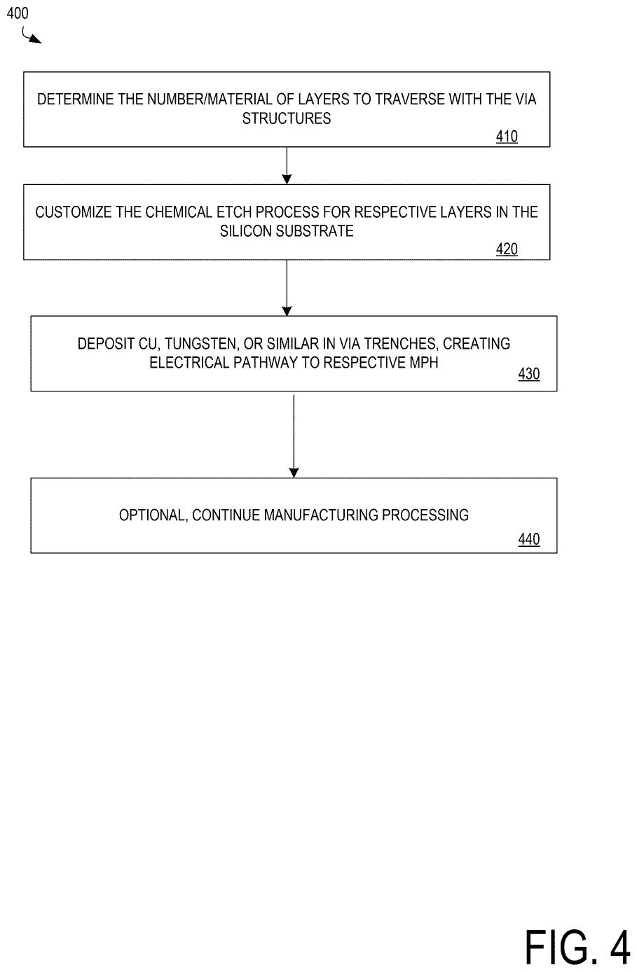

FIG. 4 is an example method for making embodiments described herein. At 410, the number and material making up individual layers of a semiconductor substrate is determined. Further, at 410, it is determined how many of the layers shall be traversed by the supervias or via structures. Specifically, at 410, it is determined, for a semiconductor substrate, a number of layers to traverse with a via. Further, at 410, it is determined a first type of material of a first layer of the number of layers, and a second type of material of a second layer of the number of layers. In various embodiments, there will additionally be a third layer and third type of material, fourth layer and fourth type of material, and etc. The type of material can be a metal, a specific metal, an insulating material/specific insulating material, an oxide/specific oxide, etc.

At 420, the manufacturing process is customized, and specifically the chemical etch process is customized to create/form the via structures to have the height and taper desired. The height and taper reflect the target application's need for power delivery. Additionally, 420 includes performing the chemical etch to form the via trenches. Specifically, at 420, at least one via trench (via structure) is formed in the semiconductor substrate, wherein forming the via trench includes etching the first layer of the number of layers, responsive to the first material, and etching the second layer of the number of layers, responsive to the second material.

At 430, a conductive material is deposited into the at least one via trench (supervias); in other words, at 430, copper, tungsten, tungsten doped carbon, or a similar material, is deposited in the via structure cavities created by the chemical etch at 420.

At 440, further manufacturing processing tasks may be performed. For example, two dies may be hybrid bonded together as illustrated in FIG. 3, a multi-die assembly may have solder balls attached and may be attached to a motherboard or printed circuit board via solder balls. Microelectronic assembly may have thermal solutions attached and may have a power supply attached thereto, and etc. A finished final semiconductor package assembly may be placed into a housing.

Thus, embodiments of via structures for hybrid bonding architectures and methods for making same have been provided. Embodiments provide numerous advantages over available solutions, such as, but not limited to:
Embodiments replace the existing via layer with a higher density metal layer that can support higher current than available approaches.
Embodiments introduce segmented via structures to increase flexibility in etching and plating stages of manufacturing.
Embodiments of the via structures may be used for the front side metals (GMx), backside metals (BMx) and/or package side metals (PSM).
Embodiments enable optimizing the via resistance, lithography registration margin, and silicon footprint.
Via profiles post-etch of embodiments have minimal necking, bowing, notches during layer transitions, which enables a seamless barrier seed deposition and void-free metal fill.
Embodiments improve via landing health across wafer and structures; these improvements have been verified using electrical measurements.

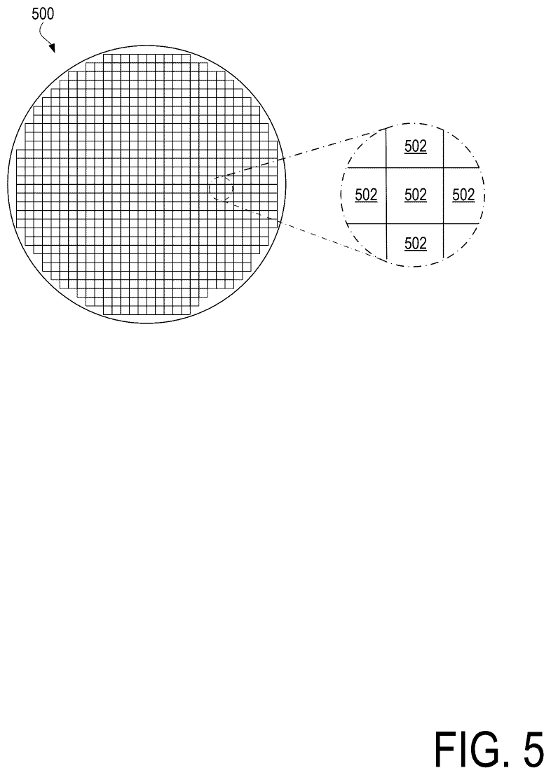

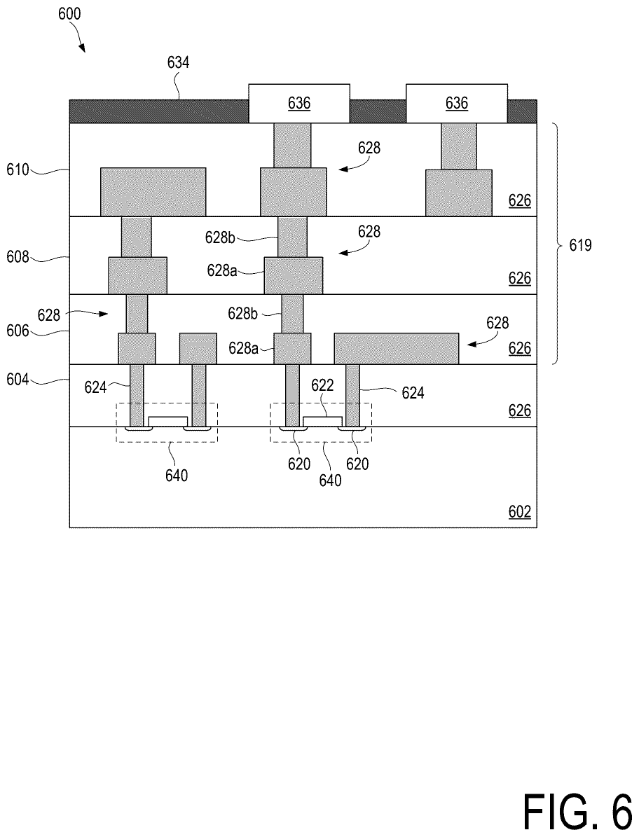

The following figures and description provide context and supporting information for the embodiments described above. FIG. 5 is a top view of a wafer 500 and dies 502 that may be included in any of the embodiments disclosed herein. The wafer 500 may be composed of semiconductor material and dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The dies 502 may be any of the dies disclosed herein. The dies 502 may include one or more transistors (e.g., transistors 640 of FIG. 6, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 500 or the dies 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the microelectronic assemblies or apparatus'disclosed herein may be manufactured using a die-to-wafer assembly technique in which some dies are attached to a wafer 500 that include others of the dies, and the wafer 500 is subsequently singulated.

FIG. 6 is a cross-sectional view of an integrated circuit structure 600 that may be included in any of the embodiments disclosed herein. Multiple instances of the integrated circuit structure 600 may be included in the dies 502 (FIG. 5). The integrated circuit structure 600 may be formed on a die substrate 602).

The die substrate 602 may be a semiconductor substrate composed of semiconductor material including, for example, n-type or p-type materials (or a combination of both). The die substrate 602 may include, for example, a crystalline substrate formed using a bulk silicon or a silicon-on-insulator (SOI) substructure. In some embodiments, the die substrate 602 can comprise a layer of silicon on top of an SOI layer with bulk silicon below the SOI layer. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit structure 600 may be used. The die substrate 602 may be part of a singulated die (e.g., dies 502 of FIG. 5) or a wafer (e.g., wafer 500 of FIG. 5).

The integrated circuit structure 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, source and drain regions (S/D regions 620), a gate 622 to control current flow between the S/D regions 620, and S/D contacts 624 to route electrical signals to and from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

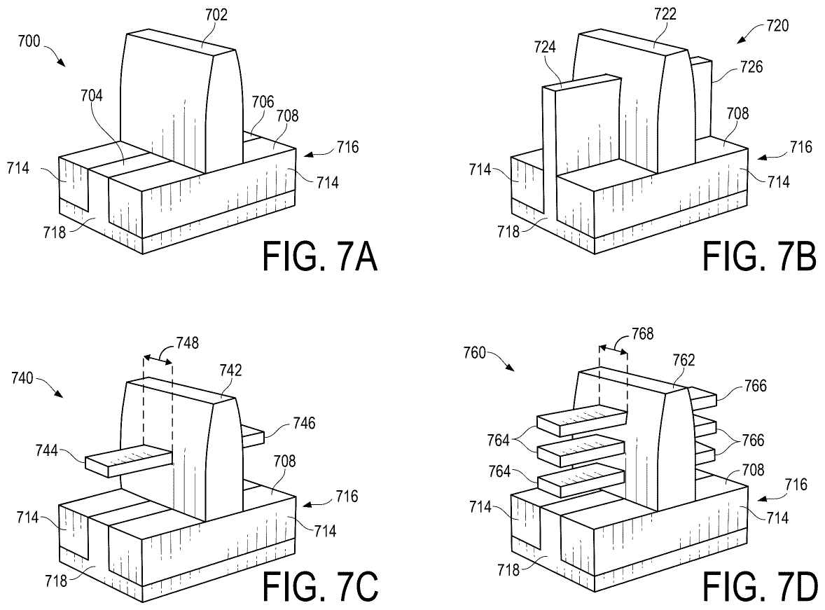

FIGS. 7A-7D are perspective views of example planar, FinFET, gate-all-around, and stacked gate-all-around transistors. The transistors illustrated in FIGS. 7A-7D are formed on a substrate 716 having a substrate surface 708 and a bulk region 718. Isolation regions 714 separate the source and drain regions of the transistors from other transistors.

FIG. 7A is a perspective view of an example transistor 700 comprising a gate 702 that controls current flow between a source region 704 and a drain region 706. The transistor 700 is planar in that the source region 704, the drain region 706 and the substrate surface 708 lie in the same plane.

FIG. 7B is a perspective view of an example transistor 720 comprising a gate 722 that controls current flow between a source region 724 and a drain region 726. The transistor 720 is non-planar in that the source region 724 and the drain region 726 comprise “fins” that extend upwards from the substrate surface 708. The transistor 720 can be referred to as a FinFET. As the gate 722 encompasses three sides of the fin that extends from the source region 724 to the drain region 726, the transistor 720 can be considered a tri-gate transistor. FIG. 7B illustrates one S/D fin extending through the gate 722, but multiple S/D fins can extend through the gate of a FinFET transistor.

FIG. 7C is a perspective view of a transistor 740 comprising a gate 742 that controls current flow between a source region 744 and a drain region 746. The transistor 740 is non-planar in that the source region 744 and the drain region 746 lie in a different plane than the substrate surface 708. As the gate 742 encompasses all sides of the channel region of the transistor 740 that extends from the source region 744 to the drain region 746, the transistor 740 can be referred to as a gate-all-around (GAA) transistor.

FIG. 7D is a perspective view of a transistor 760 comprising a gate 762 that controls current flow between multiple elevated source regions 764 and multiple elevated drain regions 766. The transistor 760 is a stacked GAA transistor as the gate controls the flow of current between multiple elevated S/D regions stacked on top of each other. The transistors 740 and 760 are considered gate-all-around transistors as the gates encompass all sides of the channel regions of the transistor that extends from the source regions to the drain regions. The transistors 740 and 760 can alternatively be referred to as nanowire, nanosheet, or nanoribbon transistors depending on the width (e.g., widths 748 and 768 of transistors 740 and 760, respectively) of the channel regions extending through the gate.

Returning to FIG. 6, transistors 640 may include a gate 622 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 7B, the gate electrode may have an upside-down U-shape that includes a top portion substantially parallel to the surface of the die substrate 602 and two side portions that are substantially perpendicular to the top surface of the die substrate 602. In other embodiments, such as the planar FET illustrated in FIG. 7A, at least one of the metal layers that form the gate electrode may be a planar layer that is substantially parallel to the top surface of the die substrate 602 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 620 may be formed within the die substrate 602 adjacent to the gate 622 of transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse further into the die substrate 602 may follow the ion implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or information-carrying signals (e.g., input/output (I/O) signals, may be routed to and/or from devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with interconnect structures 628 of the interconnect layers 606-610. The one or more interconnect layers 606-610 may form a metallization stack 619 (which can also be referred to as an “ILD stack” (inter-layer dielectric stack)) of the integrated circuit structure 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit structures having more or fewer interconnect layers than depicted.

In some embodiments, the interconnect structures 628 may include traces or lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, lines 628a of different interconnect layers 606-610 are electrically coupled by vias 628b.

The interconnect layers 606-610 may include a dielectric material 626 within which the interconnect structures 628 are disposed, as shown in FIG. 6. In some embodiments, dielectric material 626 in different ones of the interconnect layers 606-610 may have different compositions; in other embodiments, the composition of the dielectric material 626 between different interconnect layers 606-610 may be the same. The device layer 604 may include a dielectric material 626 within which the transistors 640 are disposed and upon which a bottom layer of the metallization stack is located. The dielectric material 626 that is part of the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (which can be referred to as a Metal 1 or “M1” layer) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (which can be referred to as a Metal 2 or “M2” layer) may be formed directly on the first interconnect layer 606. In some embodiments, the second interconnect layer 608 may include vias 628b to couple the lines 628a of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (which can be referred to as a Metal 3 or “M3” layer) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit structure 600 (i.e., farther away from the device layer 604) may be thicker than the interconnect layers that are lower in the metallization stack 619, with lines 628a and vias 628b in the higher interconnect layers being thicker than those in the lower interconnect layers.

The integrated circuit structure 600 may include a solder resist material 634 (e.g., polyimide or similar material) and conductive contacts 636 formed on the stack of interconnect layers 606-610. In FIG. 6, the conductive contacts 636 are illustrated as taking the form of bond pads. The conductive contacts 636 may be electrically coupled with interconnect structures 628 of the top-most layer in the metallization stack 619 and configured to route electrical signals between the transistors 640 and components external to the integrated circuit structure 600. For example, solder bonds may be formed on the conductive contacts 636 to mechanically and/or electrically couple an integrated circuit component comprising the integrated circuit structure 600 with another component (e.g., a printed circuit board). The integrated circuit structure 600 may include additional or alternate structures to route electrical signals from the interconnect layers 606-610; for example, the conductive contacts 636 may include other analogous features (e.g., posts) that can route the electrical signals between the transistors 640 and external components. The conductive contacts 636 may serve as the conductive contacts ###or ###, as appropriate.

In some embodiments in which the integrated circuit structure 600 is part of a double-sided die, the integrated circuit structure 600 may include a second metallization stack (not shown) located on the opposite side of the die substrate 602 from the device layer 604. This second metallization stack may include multiple interconnect layers as discussed above with reference to the interconnect layers 606-610. Through-silicon vias (TSVs) that extend through the die substrate 602 can provide electrically conductive pathways from the transistors 640 to the second metallization stack and the second metallizaton stack can electrically couple the TSVs to additional conductive contacts (not shown) located on the opposite side of the integrated circuit structure 600 from the conductive contacts 636.

In some embodiments, TSVs extending through the die substrate 602 can be used for routing power and ground signals from conductive contacts located on the opposite side of the integrated circuit structure 600 from the conductive contacts 636 to the transistors 640 and any other components integrated into the integrated circuit structure 600, and the metallization stack 619 can be used to route information-carrying signals from the conductive contacts 636 to transistors 640 and any other components integrated into the integrated circuit structure 600. Put another way, the routing of power and ground signals to the transistors 640 can be separated (via a back-side or bottom-side metallizaton stack and TSVs) from the routing of information-carrying signals to the transistors. The power and ground signals are provided by a backside or bottom-side metallization stack and TSVs, and information-carrying signals are provided by a topside metallization stack (e.g., metallization stack 619).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

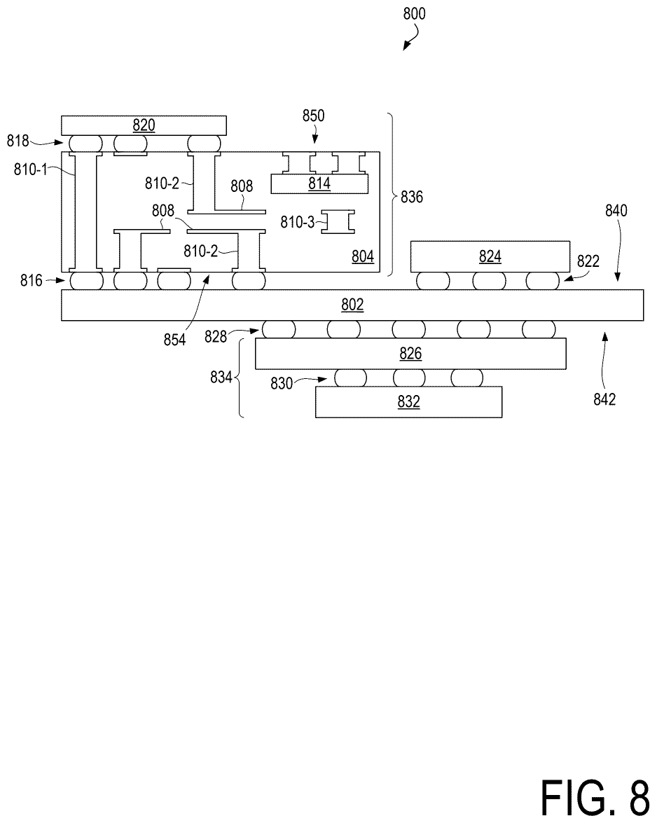

FIG. 8 is a cross-sectional view of an integrated circuit device assembly 800 that may include any of the embodiments disclosed herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and a second face 842 of the circuit board 802, the second face 842 opposing the first face 840. Generally, components may be disposed on either or both of the first face 840 and the second face 842 of the circuit board 802. Any of the integrated circuit components discussed below with reference to the integrated circuit device assembly 800 may take the form of any suitable ones of the embodiments of the microelectronic assemblies disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 802. In other embodiments, the circuit board 802 may be a non-PCB substrate.

The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802 and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 816 may serve as the coupling components illustrated or described for any substrate assembly or substrate assembly components described herein (e.g., integrated circuit components), as appropriate.

The package-on-interposer structure 836 may include an integrated circuit component 820 coupled to an interposer 804. The interposer 804 may provide an intervening substrate used to bridge the circuit board 802 and the integrated circuit component 820. The integrated circuit component 820 is coupled to the interposer 804 by coupling components 818. The coupling components 818 may take any suitable form, such as the forms discussed above with reference to the coupling components 816. Although FIG. 8 shows just one integrated circuit component attached to the interposer, multiple integrated circuit components may be coupled to the interposer 804. Additional interposers may be coupled to the interposer 804.

The integrated circuit component 820 may be a packaged or unpacked integrated circuit product that includes one or more integrated circuit dies (e.g., the die 502 of FIG. 5, a die comprising the integrated circuit structure 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider or narrower pitch or reroute a connection to a different connection. For example, the interposer 804 may couple coupling components 818 having a first pitch to coupling components 816 having a wider pitch than the first pitch. In the embodiment illustrated in FIG. 8, the integrated circuit component 820 and the circuit board 802 are attached to opposing sides of the interposer 804. In other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias, including but not limited to through hole vias 810-1 (that extend from a first face 850 of the interposer 804 to a second face 854 of the interposer 804), blind vias 810-2 (that extend from the first face 850 or the second face 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

In some embodiments the interposer 804, as well as the circuit board 802, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 804 or circuit board 802 to the glass layer. The glass layer can comprise through-glass vias (TGVs) that extend through the glass layer to provide electrically conductive paths through the glass core, glass substrate, or glass layer.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 further includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

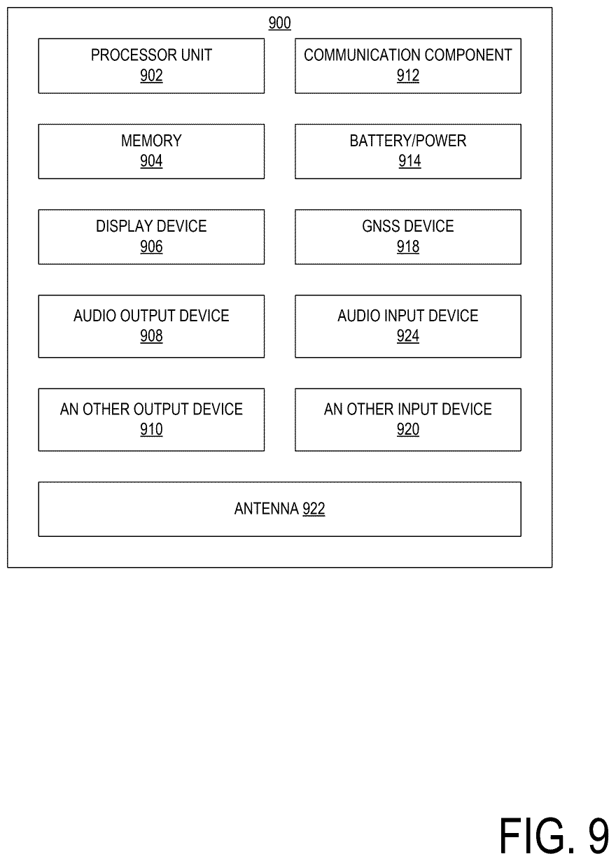

FIG. 9 is a block diagram of an example electrical device 900 that may include any of the microelectronic assemblies disclosed herein. For example, any suitable ones of the components of the electrical device 900 may include one or more of the integrated circuit device assembly 800, integrated circuit component 820, or integrated circuit structure 600, integrated circuit dies 502 disclosed herein, and may be arranged in any of the microelectronic assemblies disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the one or more processor units 902. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 900, a first one of the one or more processor units 902 can be heterogeneous or asymmetric to a second one of the one or more processor units 902 in the electrical device 900. There can be a variety of differences between the one or more processor units 902 in a system in terms of a spectrum of metrics of merit including architectural, microarchitectural, thermal, power consumption characteristics, and the like. These differences can effectively manifest themselves as asymmetry and heterogeneity among the one or more processor units 902 in the electrical device 900.

In some embodiments, the electrical device 900 may include a communication component 912. For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). In some embodiments, the electrical device 900 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such as speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System device (GNSS) (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used in this application and the claims, a list of items joined by the term “and/or” can mean any combination of the listed items. For example, the phrase “A and/or B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual [of]” or “respective [of]” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.
Example 1 is an apparatus comprising: a semiconductor substrate comprising a first surface and a second surface; the second surface comprising an insulating material with a plurality of conductive contacts arranged therein at a pitch of less than about 4 microns; a first layer of metal below the second surface; a second layer of metal below the first layer of metal and separated therefrom by an insulating layer; wherein a first conductive contact of the plurality of conductive contacts is electrically coupled to the first layer of metal; and wherein a second conductive contact, next to the first conductive contact, is electrically coupled to the second layer of metal.
Example 2 includes the subject matter of Example 1, further comprising: a via structure having a first end and a second end; wherein the second end is electrically coupled to the second conductive contact and the first end is electrically coupled to the second layer of metal; and the via structure comprises copper or tungsten.
Example 3 includes the subject matter of Example 2, wherein: the via structure comprises a first diameter at the first end and a second diameter at the second end; and wherein the second diameter is about 70% of the first diameter.
Example 4 includes the subject matter of Example 2, wherein: the via structure has an aspect ratio defined by a first end diameter and a height; and the aspect ratio is about 1/10.
Example 5 includes the subject matter of Example 2, wherein: the via structure comprises a sidewall that tapers from the first end inward to the second end; and the sidewall comprises a first segment with a first slope represented by a first angle, and a second segment with a second slope represented by a second angle, the second angle is more than 5 degrees smaller than the first angle.
Example 6 includes the subject matter of Example 5, wherein the second segment is associated with a layer of the semiconductor substrate that has silicon and nitrogen.
Example 7 includes the subject matter of Example 2, wherein: the via structure comprises a sidewall that tapers from the first end inward to the second end; and the sidewall is characterized by multiple segments; wherein some segments of the multiple segments correspond to a layer of dielectric material between two layers comprising silicon, carbon, and nitrogen.
Example 8 includes the subject matter of Example 1, further comprising one or more additional layers of metal below the first layer of metal.
Example 9 is a semiconductor package, comprising: a die having a first surface and a second surface; a plurality of conductive contacts arranged in an insulating material in the second surface, at a pitch of less than about 4 microns; a first layer of metal below the plurality of conductive contacts, the first layer of metal has a thickness of about 4.5 microns; a second layer of metal below the first layer of metal and separated therefrom by an insulating layer; a via structure in the die, the via structure comprising copper or tungsten and electrically coupled at a first end to a first conductive contact of the plurality of conductive contacts, and electrically coupled at a second end to the second layer of metal; and wherein a second conductive contact sequentially next to the first conductive contact is electrically coupled to the first layer of metal.
Example 10 includes the subject matter of Example 9, wherein the die is a first die, and further comprising: a second die attached to the first die, creating an interface; the second die having another insulating material and another plurality of conductive contacts; wherein the interface is characterized by the plurality of conductive contacts directly attached to the another plurality of conductive contacts and the insulating material directly attached to another insulating material.
Example 11 includes the subject matter of Example 9, further comprising: solder balls attached to the first surface; and a printed circuit board attached to the solder balls.
Example 12 includes the subject matter of Example 9, wherein the via structure comprises a first diameter at the first end and a second diameter at the second end; and wherein the second diameter is about 70% of the first diameter.
Example 13 includes the subject matter of Example 9, wherein: the via structure has an aspect ratio defined by a first end diameter and a height; and the aspect ratio is about 1/10.
Example 14 includes the subject matter of Example 9, wherein: the via structure comprises a sidewall that tapers from the first end inward to the second end; and the sidewall comprises a first segment with a first slope represented by a first angle, and a second segment with a second slope represented by a second angle, the second angle is more than 5 degrees smaller than the first angle.
Example 15 includes the subject matter of Example 14, wherein the second segment is associated with a layer comprising silicon and nitrogen.
Example 16 includes the subject matter of Example 9, wherein: the via structure comprises a sidewall that tapers from the first end inward to the second end; and the sidewall is characterized by multiple segments; wherein some segments of the multiple segments correspond to a layer of dielectric material between two layers comprising silicon, carbon, and nitrogen.
Example 17 includes the subject matter of Example 9, further comprising one or more additional layers of metal below the first layer of metal.
Example 18 is a method, comprising: determining, for a semiconductor substrate, a number of layers to traverse with a via; determining a type of material for respective layers of the number of layers; customizing a chemical etch process responsive to the type of material for the respective layers; forming at least one via trench in the semiconductor substrate with the customized chemical etch process; and depositing a conductive material in the at least one via trench.
Example 19 includes the subject matter of Example 18, wherein the conductive material comprises copper.
Example 20 includes the subject matter of Example 18, wherein the conductive material comprises tungsten.

What is claimed is:

1. An apparatus comprising:
a semiconductor substrate comprising a first surface and a second surface;
the second surface comprising an insulating material with a plurality of conductive contacts arranged therein at a pitch of less than about 4 microns;
a first layer of metal below the second surface;
a second layer of metal below the first layer of metal and separated therefrom by an insulating layer;
wherein a first conductive contact of the plurality of conductive contacts is electrically coupled to the first layer of metal; and
wherein a second conductive contact, next to the first conductive contact, is electrically coupled to the second layer of metal.

2. The apparatus of claim 1, further comprising:
a via structure having a first end and a second end;
wherein the second end is electrically coupled to the second conductive contact and the first end is electrically coupled to the second layer of metal; and
the via structure comprises copper or tungsten.

3. The apparatus of claim 2, wherein:
the via structure comprises a first diameter at the first end and a second diameter at the second end; and
wherein the second diameter is about 70% of the first diameter.

4. The apparatus of claim 2, wherein:
the via structure has an aspect ratio defined by a first end diameter and a height; and
the aspect ratio is about 1/10.

5. The apparatus of claim 2, wherein:
the via structure comprises a sidewall that tapers from the first end inward to the second end; and
the sidewall comprises a first segment with a first slope represented by a first angle, and
a second segment with a second slope represented by a second angle, the second angle is more than 5 degrees smaller than the first angle.

6. The apparatus of claim 5, wherein the second segment is associated with a layer of the semiconductor substrate that has silicon and nitrogen.

7. The apparatus of claim 2, wherein:
the via structure comprises a sidewall that tapers from the first end inward to the second end; and
the sidewall is characterized by multiple segments;
wherein some segments of the multiple segments correspond to a layer of dielectric material between two layers comprising silicon, carbon, and nitrogen.

8. The apparatus of claim 1, further comprising one or more additional layers of metal below the first layer of metal.

9. A semiconductor package, comprising:
a die having a first surface and a second surface;
a plurality of conductive contacts arranged in an insulating material in the second surface, at a pitch of less than about 4 microns;
a first layer of metal below the plurality of conductive contacts, the first layer of metal has a thickness of about 4.5 microns;
a second layer of metal below the first layer of metal and separated therefrom by an insulating layer;
a via structure in the die, the via structure comprising copper or tungsten and electrically coupled at a first end to a first conductive contact of the plurality of conductive contacts, and electrically coupled at a second end to the second layer of metal; and
wherein a second conductive contact sequentially next to the first conductive contact is electrically coupled to the first layer of metal.

10. The semiconductor package of claim 9, wherein the die is a first die, and further comprising:
a second die attached to the first die, creating an interface;
the second die having another insulating material and another plurality of conductive contacts;
wherein the interface is characterized by the plurality of conductive contacts directly attached to the another plurality of conductive contacts and the insulating material directly attached to another insulating material.

11. The semiconductor package of claim 9, further comprising:
solder balls attached to the first surface; and
a printed circuit board attached to the solder balls.

12. The semiconductor package of claim 9, wherein
the via structure comprises a first diameter at the first end and a second diameter at the second end; and
wherein the second diameter is about 70% of the first diameter.

13. The semiconductor package of claim 9, wherein:
the via structure has an aspect ratio defined by a first end diameter and a height; and
the aspect ratio is about 1/10.

14. The semiconductor package of claim 9, wherein:
the via structure comprises a sidewall that tapers from the first end inward to the second end; and
the sidewall comprises a first segment with a first slope represented by a first angle, and
a second segment with a second slope represented by a second angle, the second angle is more than 5 degrees smaller than the first angle.

15. The semiconductor package of claim 14, wherein the second segment is associated with a layer comprising silicon and nitrogen.

16. The semiconductor package of claim 9, wherein:
the via structure comprises a sidewall that tapers from the first end inward to the second end; and
the sidewall is characterized by multiple segments;
wherein some segments of the multiple segments correspond to a layer of dielectric material between two layers comprising silicon, carbon, and nitrogen.

17. The semiconductor package of claim 9, further comprising one or more additional layers of metal below the first layer of metal.

18. A method, comprising:
determining, for a semiconductor substrate, a number of layers to traverse with a via;
determining a first type of material of a first layer of the number of layers;
determining a second type of material of a second layer of the number of layers;
forming at least one via trench in the semiconductor substrate, wherein forming the via trench includes etching the first layer of the number of layers, responsive to the first material, and etching the second layer of the number of layers, responsive to the second material; and
depositing a conductive material in the at least one via trench.

19. The method of claim 18, wherein the conductive material comprises copper.

20. The method of claim 18, wherein the conductive material comprises tungsten.
